(19) United States
(12) Patent Application Publication
(10) Pub. No.: US 2010/0259979 A1
(43) Pub. Date: Oct. 14, 2010

(54) Self Limiting Method For Programming A Non-volatile Memory Cell To One Of A Plurality Of MLC Levels

(76) Inventors: James Yingbo Jia, Fremont, CA (US); Douglas Lee, San Jose, CA (US); Bomy Chen, Cupertino, CA (US)

Correspondence Address: DLA PIPER LLP (US ), 2000 UNIVERSITY AVENUE, EAST PALO ALTO, CA, 94303-2248, US

(21) Appl. No.: 12/422,175

(22) Filed: Apr. 10, 2009

(51) Int. Cl. G11C 16/04; G11C 7/06

(52) U.S. Cl. 365/185.03; 365/185.18; 365/189.07

(57) ABSTRACT

A flash memory cell is of the type having a substrate of a first conductivity type having a first region of a second conductivity type at a first end, and a second region of the second conductivity type at a second end, spaced apart from the first end, with a channel region between the first end and the second end, a floating gate insulated from a first portion of the channel region and adjacent to the second region, a first control gate adjacent to the floating gate and insulated therefrom, and insulated from a second portion of the channel region, and adjacent to the first region, a second control gate capacitively coupled to the floating gate, and positioned over the floating gate. A method programming the cell to one of a plurality of MLC states comprises applying a current source to the first region. A first voltage is applied to the first control gate sufficient to turn on the second portion of the channel region. A second voltage is applied to the second region, sufficient to cause electrons to flow from the first region towards the second region. A third voltage is applied to the second control gate sufficient to cause electrons in the channel region to be injected onto the floating gate. The third voltage is applied uninterrupted until the floating gate is programmed to the one state.

### TECHNICAL FIELD

The present invention relates to a method for programming a non-volatile memory cell having a floating gate to store charges, and wherein the programming method is self limiting and is useful for MLC programming.

### BACKGROUND OF THE INVENTION

Floating gate based non-volatile memory cells are well known in the art. Typically, they have been of two types, split gate or stacked gate, both of which are well known in the art. With respect to split gate, see for example, U.S. Pat. Nos. 6,747,310 and 7,046,552.

Methods to program a floating gate based non-volatile memory cell are well known in the art. See for example U.S. Pat. No. 5,029,130 assigned to the present assignee, describing a programming method to program a floating gate to a single state (programmed state), using hot electrons to be injected from a channel region into the floating gate. The electrons injected onto the floating gate continue until the charged floating gate can no longer sustain a high surface potential underneath, to generate the hot electrons. At that point, the electrons in the floating gate will “turn off” the electrons from flowing from the source onto the floating gate (see col. 4, lines 62-68). Thus, as described, the process is a self-limiting one in that voltages are applied uninterrupted until the electrons can no longer be injected onto the floating gate.

For MLC, or multi-Level Cell programming in which a floating gate can be programmed into a plurality of states, the prior art teaches a different method. In U.S. Pat. No. 7,254,071, a method is described wherein a selected number of pulses are applied. Afterwards, the state of the floating gate is “read’ or “verified”. If the verified state matches the intended state, then the programming sequence stops. If however, programming had not reached the desired state, then usually, the voltage is increased and a number of additional pulses are applied (see col. 8, lines 3-20).

The problem with a program and verify sequence is that it takes time to read or verify the state. Thus, it is desired to decrease the programming time requited to program a floating gate based non-volatile cell into one of a plurality of states.

### SUMMARY OF THE INVENTION

Accordingly, in the present invention, a method is disclosed to program a non-volatile memory cell to one of a plurality of states, representing multi-level bits. The non-volatile memory cell is of the type that has a substrate of a first conductivity type having a first region of a second conductivity type at a first end, and a second region of the second conductivity type at a second end, spaced apart from the first end, with a channel region between the first end and the second end. A floating gate is insulated from a first portion of the channel region and is adjacent to the second region. A first control gate is adjacent to the floating gate and is insulated therefrom, and is also insulated from a second portion of the channel region, and is adjacent to the first region. A second control gate is capacitively coupled to the floating gate, and is positioned over the floating gate. The method of the present invention involves the application of a current source to the first region. A first voltage is applied to the first control gate sufficient to turn on the second portion of the channel region. A second voltage is applied to the second region, sufficient to cause electrons to flow from the first region towards the second region. A third voltage is applied to the second control gate sufficient to cause electrons in the channel region to be injected onto the floating gate. The third voltage is applied uninterrupted until the floating gate is programmed to the one state.

### BRIEF DESCRIPTION OF THE DRAWINGS

FIG. 1 is a cross-sectional view of a non-volatile memory cell of the type with which the method of the present invention can be practiced.

FIG. 2 is a graph of cell programming current as a function of different control gate (CG) biases.

FIG. 3 is a graph of cell read current as a function of different control gate biases during programming. Different programmed states of cell levels can be defined as a function of either the control gate voltage or the cell current.

FIG. 4 is a graph of cell Vt (measured from the control gate) versus the bias on the control gate during programming. Different programmed states of cell levels are shown as a function of the control gate voltage or the cell Vt.

FIG. 5 is a block level circuit diagram for programming a plurality of cells simultaneously using the method of the present invention.

FIG. 6 is a schematic block diagram of a method of setting the wafer level calibration of programming for different cell levels.

FIG. 7 is a circuit showing the variation in cell current read out as a function of its location due to the resistance on the source line.

FIG. 8 is a embodiment of a circuit to be used as a reference cell in the reading of a MLC cell shown in FIG. 7.

### DETAILED DESCRIPTION OF THE INVENTION

Referring to FIG. 1, there is shown a cross-sectional view of a non-volatile memory cell 10 with which the method of the present invention may be used. The cell 10 comprises a substrate 12 of a semiconductor material of a first conductivity type, such as P type. The substrate 12 has a planar surface 14. Along the planar surface 14 is a first region 16 of a second conductivity type (labeled as BL in FIG. 1), such as N type. Spaced apart from the first region 16 is a second region 18 of the second conductivity type (labeled as SL). Between the first region 16 and the second region 18 is a channel region 20. A first control gate 22 (labeled WL) is positioned over a first portion of the channel region 20. The first control gate 22 is insulated from the substrate 12. A floating gate 24 (labeled FG) is positioned over a second portion of the channel region 20 and is also insulated and spaced apart from the first control gate 22. A portion of the floating gate 24 may also be positioned over a portion of the second region 18, and insulated therefrom. A second control gate 26 (labeled CG) is positioned above the floating gate 24 and is insulated therefrom. The second control gate 26 is also insulated and spaced apart from both the floating gate 24 as well as the first control gate 22. Finally, an erase gate 28 is positioned over the second region 18, and insulated therefrom, and is also laterally spaced apart and insulated from the floating gate 24 and the second control gate 26.

The method of the present invention may be used with the non-volatile cell 10 shown and described in FIG. 1, with the erase gate 28 being optional.

In the method of the present invention, to program the cell 10 to a state, which is one of a plurality of states (i.e. to program the cell 10 to an MLC level), the following electrical parameters are applied to the various components of the cell 10. A current source is applied to the first region 16. A first voltage is applied to the first control gate 22 sufficient to turn on the first portion of the channel region 20. A second voltage is applied to the second region 18 sufficient to attract electrons from the first region 16 to traverse the channel region 20 in the direction of the second region 18. A third voltage is applied to the second control gate 26 sufficient to cause the electrons in the channel region 20 to be injected onto the floating gate 24. The third voltage is applied continuously and uninterruptedly until the floating gate 24 is programmed to the one state. When the one state is reached the electrons injected on the floating gate 24 can no longer sustain a high surface potential underneath, in the channel region 20, to generate the hot electrons. Thus, the method of the present invention is a self limiting process in that the voltage applied on the various terminals and components of the cell 10 until the floating gate is programmed to the one state at which one the process of electron injection ceases automatically.

The theory of the method of programming of the present invention is as follows. When a current is applied to the first region 16, it traverses the channel region 20 in the direction of the second region 18. With a first voltage applied to the first control gate 22, the portion of the channel region 20 directly underneath the first control gate 22 is in an inversion state or weak inversion state, permitting the electrons to traverse that region. However, because the third voltage applied to the second control gate 26 is substantially greater than the first voltage, and because the second control gate is highly capacitively coupled to the floating gate 24, there is a high lateral electric field in a gap in the channel region 20 that is between the region directly underneath the first control gate 22 and underneath the floating gate 24. Electrons from the first region 16 are accelerated in this gap by the high electric field and become hot. Some of the electrons tunnel through the insulator (typically silicon oxide) between the floating gate 24 and the substrate 12 and are injected onto the floating gate 24. The vertical electric filed caused by the high third voltage applied to the second control gate 26 assist in the electrons tunneling through the floating gate oxide onto the floating gate 24. As more electrons are injected onto the floating gate 24 however, the floating gate 24 potential becomes lower. As a result the vertical electric potential between the channel region 20 and the floating gate 24 is lowered. Eventually the decrease in vertical electric potential between the channel region 20 and the floating gate is not longer sufficient to sustain the electrons being injected onto the floating gate 24. At that point the programming of the floating gate 24 ceases.

The potential on the floating gate 24 at program saturation may be expressed mathematically as follows:

VFGP=VCGPa+VWLPb+VSPPg+VSLPm+QP/Ctot=VSAT
a=CG coupling ratio
b=WL coupling ratio
g=SP coupling ratio
m=SL coupling ratio
QP=Total charge in FG
Ctot=Total capacitance of FG
VSAT: with constant VWLP, IBL, and VSLP, where VSAT is a constant not depending on VCGP and VSPP

To program the cell 10 to a different state, the third voltage applied to the second control gate 26 is changed to a fourth voltage, different from the third voltage. All the other electrical parameters applied to the other components of the cell 10 remain the same.

An example of programming parameters for a MCL method of the present invention is as follows:

| State/Component | WL 22 | CG 26 | SL 18 | EG 28 | BL 16 |
|---|---|---|---|---|---|
| Program 00 | ~1.6 V | ~10.5 V | ~5.0 V | ~5.0 V | ~−2 uA |
| Program 01 | ~1.6 V | ~7.0 V | ~5.0 V | ~5.0 V | ~−2 uA |
| Program 10 | ~1.6 V | ~4.0 V | ~5.0 V | ~5.0 V | ~−2 uA |

In this example, different third voltages applied to the second control gate 26 is used to program the memory cell 10 to two bits per cell. Although in the example shown above, the same voltage is applied to the first control gate 22, the second region 18 and the erase gate 28, and the same current is applied to the first region 16 with only the third voltage applied to the second control gate 26 changed, the method of the present invention may also be used with different voltages applied to the first control gate 22, second region 18 and erase gate 28.

Furthermore, all of the values may be modified depending upon the cell size, and design and performance requirements.

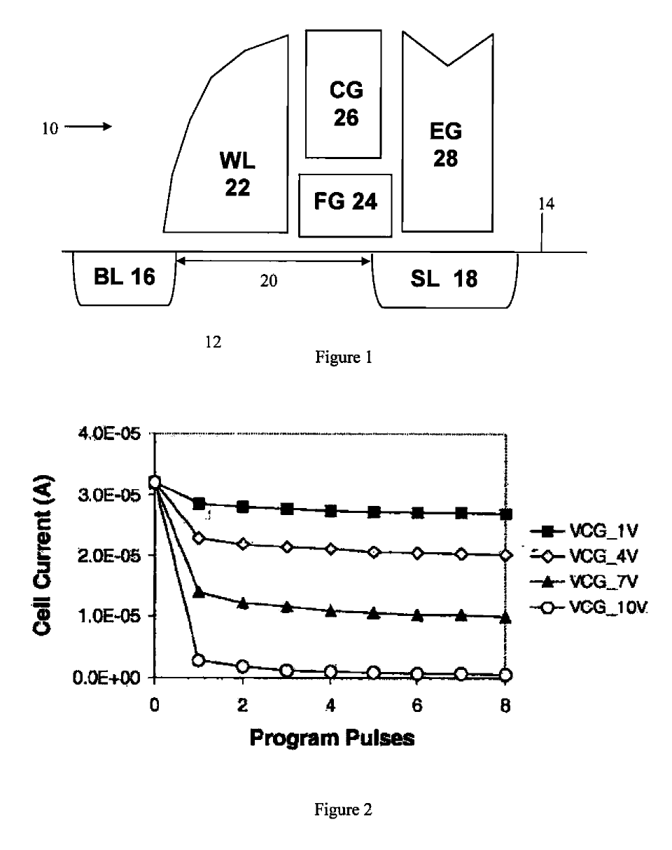

Referring to FIG. 2 there is shown a graph of the cell programming current into a cell 10 using the method of the present invention as a function of different voltage biases on the second control gate 26. As can be seen in FIG. 2, with a lower voltage on the second control gate 26, a lower amount of charge will be programmed into the floating gate 24 resulting in greater current in the cell 10.

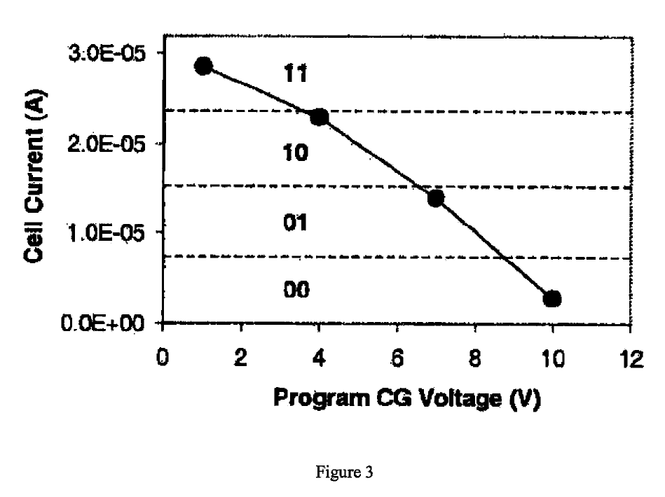

Referring to FIG. 3 there is shown a graph of cell read current as a function of different biases on the second control gate 26 during programming. Different programmed states of cell levels can be defined as a function of either the voltage on the second control gate 26 or the cell current. As can be seen from FIG. 3, when a voltage of approximately between 1 to 3 volts is applied to the second control gate 26, the cell 10 can be programmed to the state of “11”. Between approximately 3-7 volts applied to the second control gate 26, the cell 10 can be programmed to the stated of “10”. Between approximately 7-9 volts applied to the second control gate 26, the cell 10 can be programmed to the state of “01”. Finally between approximately 9-10+ volts applied to the second control gate 26, the cell 10 can be programmed to the state of “00”. Each of the foregoing voltage ranges has a corresponding cell current range.

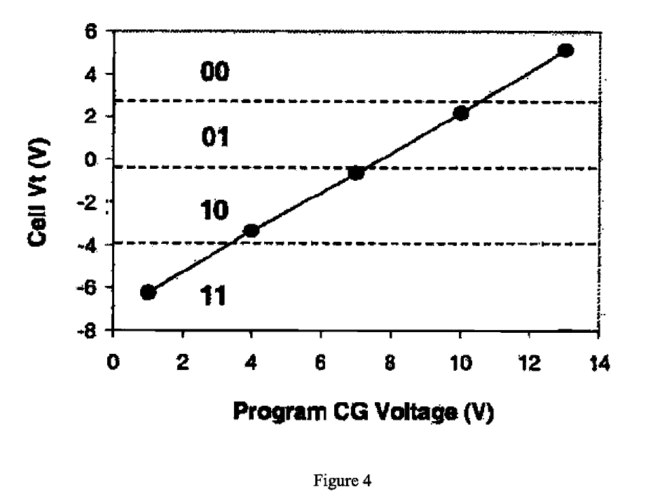

Referring to FIG. 4 there is shown a graph of cell Vt (measured from the second control gate 26) versus the bias on the second control gate 26 during programming. Different programmed states of cell levels are shown as a function of the voltage applied to the second control gate 26 or the cell Vt. As shown in FIG. 4, for example, when a voltage of approximately 1-3 volts is applied to the second control gate 26, the cell 10 can be programmed to the state of “11”. When a voltage of approximately 3-7 volts is applied to the second control gate 26, the cell 10 can be programmed to the state of “10”. When a voltage of approximately 7-10 volts is applied to the second control gate 26, the cell 10 is programmed to the state of “01”. Finally, when a voltage of approximately 10-13 volts is applied to the second control gate 26, the cell 10 is programmed to the state of “00”. The cell Vt threshold voltage corresponding to each of the states is also shown. The voltages referenced hereinabove are only examples and depend on the design of the memory cell 10, including the process geometry.

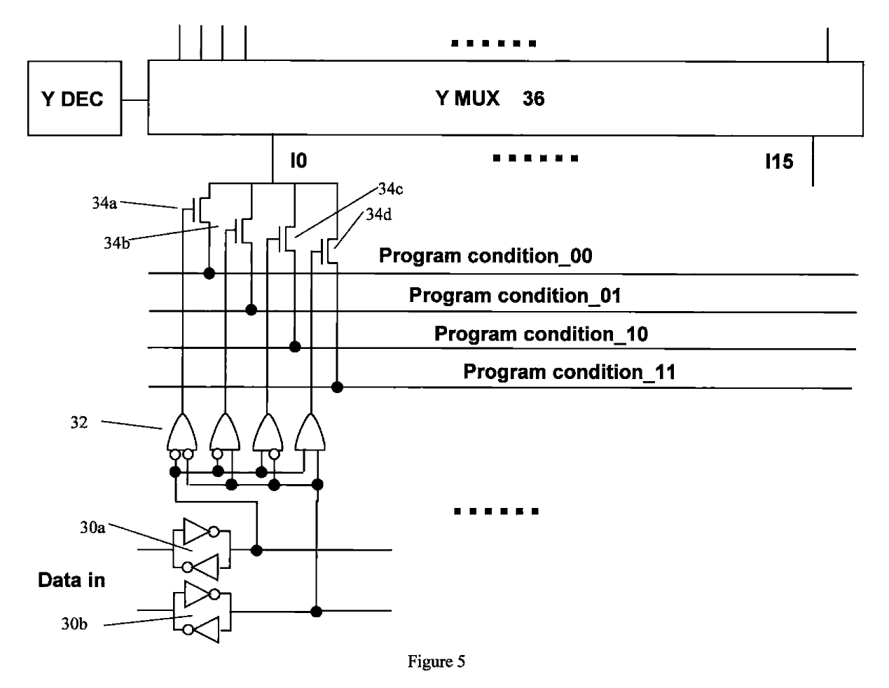

Referring to FIG. 5, there is shown a block level circuit diagram for programming a plurality of cells simultaneously using the method of the present invention. Data, e.g. “10” is supplied to and stored in two flip flops 30a and 30b. Through the combinatorial logic 32, the data “10” is supplied to four transistor gates 34(a-d) through which the programming voltages for the states “00”, “01” “10” and “11” are also supplied. The output of the combinatorial logic 32 activates only one of the four transistors 34, and the programming voltage for the state “10” is then supplied to a multiplexer 36, which supplies that programming voltage to the plurality of cells requiring that voltage. Since in the method of the present invention, the programming method is self limiting, the programming voltages can be applied to a plurality of the selected cells simultaneously until all of the cells 10 are programmed. This avoids the required steps of programming followed by verification for each one of the cells 10 programmed sequentially through the states of “00”, “01” “10” and “11” to be programmed to the desired level.

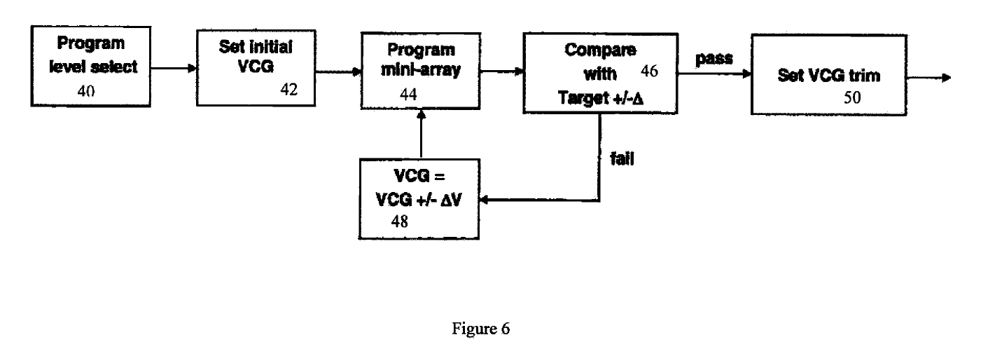

As seen from the above discussion, the voltage range applied to the second control gate 26 determines the state of the cell 10 to which it can be programmed. The voltage range, however, for a cell 10 in a die may vary from die to die even on the same wafer. Referring to FIG. 6 there is shown a block level diagram of a method of setting the reference cells in a MLC die during the wafer sort operation. During the first step of wafer sort, a program level, such as “01” or “10” is selected at step 40. The initial voltage corresponding to that state, is then set to be applied to the second control gate 26 of the memory cells 10, in step 42. The voltage set in step 42 is then applied to a mini-array of the memory cells 10 in step 44. The memory cells so programmed in step 44 are then read and the current read from each cell that is programmed is compared to a reference current level in step 46. In the event the comparison in step 46 shows that the current read from the programmed cell is within the range of the anticipated current, then the voltage set for that programmed state in step 42 is set in step 50 as the voltage for the control gate for the die. In the event the comparison in step 46 shows that the current read from the programmed cell is outside of the range of the anticipated current, then the voltage applied to the second control gate 26 is adjusted in step 48 and the mini-array is reprogrammed in step 44. Thereafter, the current is read again and is again compared to the anticipated current. In step 46. This process continues until the current read of the programmed state is within the range of the anticipated current. In this manner the variation from die to die of the correspondence of a programmed state, such as “00” or “01” or “10” or “11” to the voltage level can be corrected.

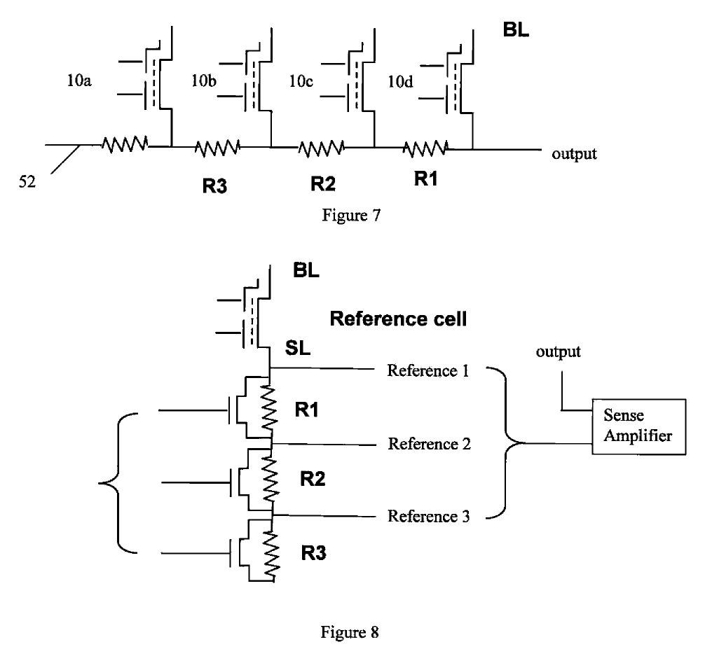

Referring to FIG. 7 there is shown a circuit diagram of a conventional plurality of memory cells 10(a-d) all connected to a common source line 52. The source line 52 is typically made out of polysilicon having resistance therein. Thus, the cell current read from any one of the memory cells 10(a-d) will depend on its location. Each cell that is read will of course, be read based upon an address signal. Since in MLC read-out the amount of the current of a memory cell is dependent on its programmed state, the resistance along the source line can cause cell current variation.

Referring to FIG. 8, there is shown a circuit diagram of a reference memory cell along with its serially connected resistors, each of which corresponds approximately to the resistance along the source line 52 between immediately adjacent memory cells 10. Thus, with the circuit shown in FIG. 8, in the event memory cell 10d is chosen to be read out, reference 1 from the circuit shown in FIG. 8 is chosen. In the event memory cell 10c is read out, the reference 2 is chosen. The address signal that is used to select the memory cell 10 in FIG. 7 is also used to select the particular resistor (and therefore, the reference node) in the circuit shown in FIG. 8. The particular reference node and the output from the source line are then supplied to a sense amplifier and compared. In this manner, the effect of the resistance from the source line 52 can be eliminated. By comparing the cell current from the circuit shown in FIG. 7 at the output node with a reference cell current having an equal amount of resistance at a reference x node, the affect of the resistance on the source line 52 can be minimized or eliminated.

From the foregoing it can be seen that a simplified method of programming a non-volatile memory cell to one of a plurality of states in a plurality bits is shown, with attending beneficial results.

What is claimed is:

1. A method of programming a non-volatile memory cell to one of a plurality of states, representing multi-level bits, wherein the non-volatile memory cell is of the type having a substrate of a first conductivity type having a first region of a second conductivity type at a first end, and a second region of the second conductivity type at a second end, spaced apart from the first end, with a channel region between the first end and the second end, a floating gate insulated from a first portion of the channel region and adjacent to the second region, a first control gate adjacent to the floating gate and insulated therefrom, and insulated from a second portion of the channel region, and adjacent to the first region, a second control gate capacitively coupled to the floating gate, and positioned over the floating gate, wherein the method comprising:
applying a current source to the first region;
applying a first voltage to the first control gate sufficient to turn on the second portion of the channel region;
applying a second voltage to the second region, sufficient to cause electrons to flow from the first region towards the second region; and
applying a third voltage to the second control gate sufficient to cause electrons in the channel region to be injected onto the floating gate;
wherein said third voltage is applied uninterrupted until the floating gate is programmed to the one state.

2. The method of claim 1 further comprising:
an erase gate positioned adjacent to the floating gate and insulated therefrom and insulated from the second region.

3. The method of claim 1 further comprising:
applying an uninterrupted fourth voltage different from the third voltage to the second control gate to program the floating gate to another state different from the one state.

4. The method of claim 1 further comprising:
programming a plurality of non-volatile memory cells to the same one state simultaneously.

5. A method of selecting the programming voltage corresponding to one of a plurality of states of a plurality of bits to be applied to an array of non-volatile memory cells on a die, wherein the method comprising:
a) selecting a desired state;
b) setting an initial programming voltage corresponding to said desired state;
c) programming a plurality of memory cells of a portion of said array by said initial programming voltage;
d) reading said programmed cells;
e) comparing the current read to the anticipated current for the desired state;
f) selecting the initial programming voltage as the programming voltage for that desired state for the array of memory cells of that die in the event the current read is within a range of the anticipated current for the desired state; and
g) adjusting the initial programming voltage in the event the current read is outside of a range of the anticipated current for the desired state; and returning to step (c).

6. The method of claim 5, wherein steps (a-g) are repeated for said plurality of states of a plurality of bits.

7. The method of claim 5 wherein each memory cell is of the type having a substrate of a first conductivity type having a first region of a second conductivity type at a first end, and a second region of the second conductivity type at a second end, spaced apart from the first end, with a channel region between the first end and the second end, a floating gate insulated from a first portion of the channel region and adjacent to the second region, a first control gate adjacent to the floating gate and insulated therefrom, and insulated from a second portion of the channel region, and adjacent to the first region, a second control gate capacitively coupled to the floating gate, and positioned over the floating gate.

8. A method of reading a selected non-volatile memory cell from a plurality of non-volatile memory cells, each of which is connected in series between a bit fine and a source line, and with each cell being in parallel to a plurality of other memory cells and connected to different portion of the source line, with a resistance between each adjacent memory cell, wherein said method comprising:
selecting the select non-volatile memory cell, said selected non-volatile memory cell having a certain resistance between its output and the input to a sense amplifier;
selecting a reference memory cell with a resistor wherein the resistor having substantially the same certain resistance between its output and the input to the sense amplifier;
comparing the current read from the select non-volatile memory cell passed through the certain resistance at the sense amplifier with the current from the reference memory cell passed through the resistor at the sense amplifier; and
determine the state of the select non-volatile based upon the comparison.

9. The method of claim 8 wherein the select memory cell is of the type having a substrate of a first conductivity type having a first region of a second conductivity type at a first end, and a second region of the second conductivity type at a second end, spaced apart from the first end, with a channel region between the first end and the second end, a floating gate insulated from a first portion of the channel region and adjacent to the second region, a first control gate adjacent to the floating gate and insulated therefrom, and insulated from a second portion of the channel region, and adjacent to the first region, a second control gate capacitively coupled to the floating gate, and positioned over the floating gate.

10. The method of claim 8 wherein the select non-volatile memory cell is selected by an address signal, and wherein the address signal is also used to select the resistor.
